(19) United States
(12) Patent Application Publication
(10) Pub. No.: US 2026/0242947 A1
(43) Pub. Date: Aug. 20, 2026

(54) SULFUR-CONTAINING SILOXANE, COMPOSITION FOR FORMING SILICON-CONTAINING FILM COMPRISING SAID SULFUR-CONTAINING SILOXANE, SULFUR-CONTAINING SILOXANE PRODUCTION METHOD, SILICON-CONTAINING FILM, AND SILICON-CONTAINING FILM PRODUCTION METHOD

(71) Applicant: SUMITOMO SEIKA CHEMICALS CO., LTD., Harima-cho, Kako-gun, Hyogo (JP)

(72) Inventors: Genki TAIRA, Harima-cho, Kako-gun, Hyogo (JP); Yoshihide UENO, Harima-cho, Kako-gun, Hyogo (JP); Hajime SHIMADA, Harima-cho, Kako-gun, Hyogo (JP)

(73) Assignee: SUMITOMO SEIKA CHEMICALS CO., LTD., Harima-cho, Kako-gun, Hyogo (JP)

(21) Appl. No.: 18/852,279

(22) PCT Filed: Mar. 27, 2023
(86) PCT No.: PCT/JP2023/012290

§ 371 Date: Sep. 27, 2024

(30) Foreign Application Priority Data
Mar. 29, 2022 (JP) 2022-054385

(51) Int. Cl. C23C 16/455; C07F 7/08; C07F 7/21; C08G 77/48; C23C 16/40

(52) U.S. Cl. CPC C23C 16/45553; C07F 7/0898; C07F 7/21; C08G 77/485; C23C 16/401

(57) ABSTRACT

The present disclosure relates to a sulfur-containing siloxane, methods of producing the same, and methods of using the same.

### TECHNICAL FIELD

The present disclosure relates to a sulfur-containing siloxane and a composition for forming a silicon-containing film containing the sulfur-containing siloxane.

### BACKGROUND ART

In fabricating semiconductor devices, silicon-containing thin films have been manufactured as various forms of thin films such as silicon films, silicon oxide films, silicon nitride films, silicon carbonitride films and silicon oxynitride films by various vapor deposition processes. The silicon-containing thin films have been applied in various fields. Among them, silicon oxide films and silicon nitride films have very excellent barrier properties and oxidation resistance, and therefore function, in fabricating the devices, as insulating films, intermetallic dielectric materials, seed layers, spacers, hard masks, trench isolation structures, diffusion preventing films, etch stop layers, and protective film layers.

In recent years, there has been a need for a technique for forming a film using an atomic layer deposition (ALD) method, which can form a uniform film, along with miniaturization of devices, an increase in aspect ratio, and diversification of device materials. In addition, in recent years, there has been a demand for a high-quality film that is low in impurities and excellent in electrical properties. As one of solutions for forming a high-quality film, a method for forming a film at a high temperature of 500° C. or more is attracting attention. However, conventional film-forming materials often decompose at a high temperature, making it difficult to be formed into films by an atomic layer deposition (ALD) method. When decomposition occurs, self-control of the film formation is difficult, making it difficult to form a uniform film, so that it may be not possible to achieve formation of a film with a high aspect ratio associated with miniaturization or the like. Therefore, there is a need for materials that do not decompose even under high temperature conditions and can be formed into films by an ALD method.

One example of conventional film-forming materials by an atomic layer deposition (ALD) method is a method proposed in Patent Literature 1, which is for forming a uniform silicon oxide film by using an aminosilane compound, bisdiethylaminosilane (BDEAS), as a silicon source.

Patent Literature 2 proposes a method for forming a uniform silicon oxide film at a high deposition rate by using an aminosilane compound, 2-dimethylamino-2,4,6,8-tetramethylcyclotetrasiloxane, as a silicon source by an atomic layer deposition (ALD) method.

Patent Literature 3 proposes a method for forming a uniform silicon oxide film at a high temperature by using an aminosilane compound, dimethylaminotrimethylsilane (DMATMS), as a silicon source by an atomic layer deposition (ALD) method.

### CITATION LIST

### Patent Literature

Patent Literature 1: Japanese Translation of PCT International Application Publication No. 2008-533731
Patent Literature 2: Japanese Patent Laid-Open No. 2018-154615
Patent Literature 3: Japanese Patent Laid-Open No. 2020-038978

### SUMMARY OF INVENTION

### Technical Problem

However, bisdiethylaminosilane described in Patent Literature 1 can form a silicon oxide film at 200 to 400° C. and 2-dimethylamino-2,4,6,8-tetramethylcyclotetrasiloxane described in Patent Literature 2 can form a silicon oxide film at 100 to 300° C., each by an ALD method. In each case, the temperature range is low, and if the film is formed at such a high temperature as 500° C. or more, the film-forming material may decompose and the film may not be formed uniformly. Dimethylaminotrimethylsilane described in Patent Literature 3 can form a silicon oxide film by an ALD method at a temperature of 500 to 650° C., which is higher than the temperature at which bisdiethylaminosilane described in Patent Literature 1 or 2-dimethylamino-2,4,6,8-tetramethylcyclotetrasiloxane described in Patent Literature 2 forms a silicon oxide film. However, this high temperature conditions are still not adequate, and furthermore, there are concerns in view of production cost because the film formation rate is as low as about 0.12 nm/cycle.

The present disclosure has made under such circumstances. It is a main object of the present disclosure to provide a novel silicon precursor that can be subjected to film formation by an atomic layer deposition (ALD) method even under high temperature conditions in the formation of a silicon-containing film.

### Solution to Problem

It has been conventionally general to use an aminosilane compound, which has an amino group bonded to a Si atom, as a precursor for forming a silicon-containing film. After diligent research, the present inventors have found that use of a thiosilane compound, which has a sulfur atom bonded to a Si atom, as a precursor for a silicon-containing film is effective for obtaining the desired effect. In particular, they have found that film formation by an atomic layer deposition (ALD) method can be achieved in a wide temperature region including high temperature conditions by using, as a silicon precursor, a particular compound having a sulfur atom bonded to a Si atom of a siloxane structure (—Si—O—Si—), and have completed the present disclosure.

One example of embodiments of the present disclosure is as follows:

### [Clause 1]

A sulfur-containing siloxane represented by the following formula (1):

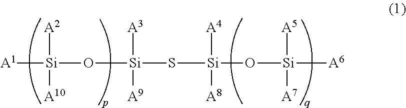

wherein, in the formula (1),
A¹ to A¹⁰, at each occurrence, are each independently a hydrogen atom, an organic group, a halogen, a siloxy group represented by OSiR^{a}R^{b}R^{c}, or an amino group represented by NR^{d}R^{e}; provided that A¹ and A³ optionally become one to be an oxygen atom to thereby form a cyclic siloxane, and provided that A⁴ and A⁶ optionally become one to be an oxygen atom to thereby form a cyclic siloxane;
R^{a} to R^{e}, at each occurrence, are each independently a hydrogen atom, or an organic group, and R^{d} and R^{e} are optionally combined with each other to form a ring; and
p and q are each independently an integer of 1 to 5.

### [Clause 2]

The sulfur-containing siloxane according to clause 1, wherein A¹ and A³ become one to be an oxygen atom to thereby form a cyclic siloxane, and A⁴ and A⁶ become one to be an oxygen atom to thereby form a cyclic siloxane.

### [Clause 3]

The sulfur-containing siloxane according to clause 1 or 2, which is represented by the following formula (2):

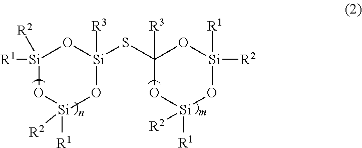

wherein, in the formula (2),
R¹ to R³, at each occurrence, are each independently a hydrogen atom, or a monovalent aliphatic hydrocarbon group having 1 to 10 carbon atoms; and
n and m are each independently an integer of 1 to 4.

### [Clause 4]

The sulfur-containing siloxane according to any one of clauses 1 to 3, which has a molecular weight of 1,000 or less.

### [Clause 5]

The sulfur-containing siloxane according to any one of clauses 1 to 4, wherein the sulfur-containing siloxane has 50 carbon atoms or less.

### [Clause 6]

The sulfur-containing siloxane according to any one of clauses 1 to 5, which is represented by the following formula (3):

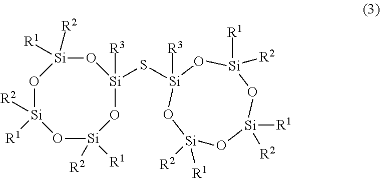

wherein, in the formula (3),
R¹ to R³, at each occurrence, are each independently a hydrogen atom, or a monovalent aliphatic hydrocarbon group having 1 to 10 carbon atoms.

### [Clause 7]

The sulfur-containing siloxane according to any one of clauses 1 to 6, which is bis(2,4,6,8-tetramethylcyclotetrasiloxanyl)sulfide represented by the following formula (4):

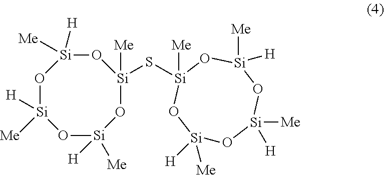 [SMILES: C[SiH]1O[SiH](C)O[Si](C)(S[Si]2(C)O[SiH](C)O[SiH](C)O[SiH](C)O2)O[SiH](C)O1]

### [Clause 8]

The sulfur-containing siloxane according to any one of clauses 1 to 7, which is represented by the following formula (5):

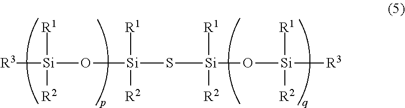

wherein, in the formula (5),
R¹ to R³, at each occurrence, are each independently a hydrogen atom, or a monovalent aliphatic hydrocarbon group having 1 to 10 carbon atoms; and
p and q are each independently an integer of 1 to 5.

### [Clause 9]

The sulfur-containing siloxane according to any one of clauses 1 to 8, which is represented by the following formula (6):

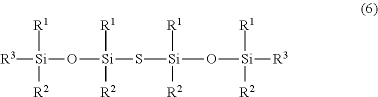

wherein, in the formula (6),
R¹ to R³, at each occurrence, are each independently a hydrogen atom, or a monovalent aliphatic hydrocarbon group having 1 to 10 carbon atoms.

### [Clause 10]

The sulfur-containing siloxane according to any one of clauses 1 to 9, which is bis(1,1,1,3,3-pentamethyldisiloxan-3-yl)sulfide represented by the following formula (7):

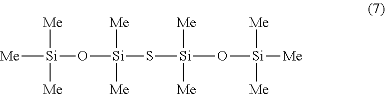 [SMILES: C[Si](C)(C)O[Si](C)(C)S[Si](C)(C)O[Si](C)(C)C]

### [Clause 11]

A precursor for a silicon-containing film, comprising the sulfur-containing siloxane according to any one of clauses 1 to 10.

### [Clause 12]

The precursor according to clause 11, wherein the silicon-containing film is formed by chemical vapor deposition.

### [Clause 13]

The precursor according to clause 11 or 12, wherein the silicon-containing film is formed by an atomic layer deposition method.

### [Clause 14]

A composition for forming a silicon-containing film, which comprises the sulfur-containing siloxane according to any one of clauses 1 to 10.

### [Clause 15]

The composition according to clause 14, wherein the silicon-containing film is formed by chemical vapor deposition.

### [Clause 16]

The composition according to clause 14 or 15, wherein the silicon-containing film is formed by an atomic layer deposition method.

### [Clause 17]

A method for producing a sulfur-containing siloxane represented by the following formula (1):

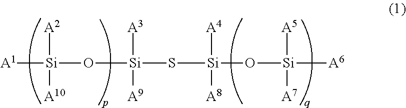

wherein, in the formula (1),
A¹ to A¹⁰, at each occurrence, are each independently a hydrogen atom, an organic group, a halogen, a siloxy group represented by OSiR^{a}R^{b}R^{c}, or an amino group represented by NR^{d}R^{e}; provided that A¹ and A³ optionally become one to be an oxygen atom to thereby form a cyclic siloxane, and provided that A⁴ and A⁶ optionally become one to be an oxygen atom to thereby form a cyclic siloxane;
R^{a} to R^{e}, at each occurrence, are each independently a hydrogen atom, or an organic group, and R^{d} and R^{e} are optionally combined with each other to form a ring; and
p and q are each independently an integer of 1 to 5;
wherein the method comprises:
(a) the step of synthesizing the sulfur-containing siloxane from a raw material siloxane; and
(b) the distillation step of isolating the sulfur-containing siloxane by distillation.

### [Clause 18]

The method for producing a sulfur-containing siloxane according to clause 17, wherein in the step (a), the raw material siloxane is reacted with a sulfurizing agent to synthesize the sulfur-containing siloxane.

### [Clause 19]

The method for producing a sulfur-containing siloxane according to clause 17 or 18, wherein the raw material siloxane is a compound represented by the following formula (8-3):

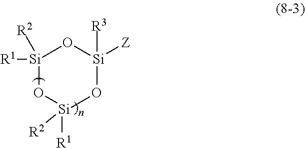

wherein, in the formula (8-3),
R¹ to R³, at each occurrence, are each independently a hydrogen atom, or a monovalent aliphatic hydrocarbon group having 1 to 10 carbon atoms;
Z is a halogen or a hydrogen atom; and
n is an integer of 1 to 4;
   or a compound represented by the following formula (8-4):

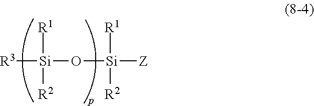

wherein, in the formula (8-4),
R¹ to R³, at each occurrence, are each independently a hydrogen atom, or a monovalent aliphatic hydrocarbon group having 1 to 10 carbon atoms;
Z is a halogen or a hydrogen atom; and
p is an integer of 1 to 5.

### [Clause 20]

A method for producing a silicon-containing film, which uses a sulfur-containing siloxane represented by the following formula (1):

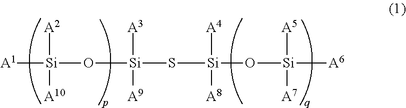

wherein, in the formula (1),
A¹ to A¹⁰, at each occurrence, are each independently a hydrogen atom, an organic group, a halogen, a siloxy group represented by OSiR^{a}R^{b}R^{c}, or an amino group represented by NR^{d}R^{e}; provided that A¹ and A³ optionally become one to be an oxygen atom to thereby form a cyclic siloxane, and provided that A⁴ and A⁶ optionally become one to be an oxygen atom to thereby form a cyclic siloxane;
R^{a} to R^{e}, at each occurrence, are each independently a hydrogen atom, or an organic group, and R^{d} and R^{e} are optionally combined with each other to form a ring; and
p and q are each independently an integer of 1 to 5.

### Advantageous Effects of Invention

According to the present disclosure, a siloxane compound having a sulfur atom can be used as a silicon precursor to form a uniform and good-quality film by an ALD method in a wide temperature region including high temperature conditions. Therefore, according to the method of the present disclosure, a uniform film having the excellent properties can be formed even under high temperature conditions, so that a high-performance semiconductor device can be fabricated.

### BRIEF DESCRIPTION OF DRAWINGS

FIG. 1 shows a ¹H-NMR chart of bis(2,4,6,8-tetramethylcyclotetrasiloxanyl)sulfide obtained by the production method in Example 1 of the present disclosure.

FIG. 2 shows the relationship between the substrate temperature and the deposition rate in each of Examples 2 and 4 and Comparative Examples 1, 2 and 3 of the present disclosure.

FIG. 3 shows a ¹H-NMR chart of bis(1,1,1,3,3-pentamethyldisiloxan-3-yl)sulfide obtained by the production method in Example 3 of the present disclosure.

### DESCRIPTION OF EMBODIMENTS

### <Sulfur-Containing Siloxane>

The sulfur-containing siloxane in the present disclosure may be a sulfur-containing siloxane represented by the following formula (1):

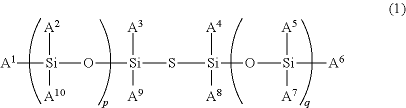

wherein, in the formula (1),
A¹ to A¹⁰, at each occurrence, are each independently a hydrogen atom, an organic group, a halogen, a siloxy group represented by OSiR^{a}R^{b}R^{c}, or an amino group represented by NR^{d}R^{e}; provided that A¹ and A³ optionally become one to be an oxygen atom to thereby form a cyclic siloxane, and provided that A⁴ and A⁶ optionally become one to be an oxygen atom to thereby form a cyclic siloxane;
R^{a} to R^{e}, at each occurrence, are each independently a hydrogen atom, or an organic group, and R^{d} and R^{e} are optionally combined with each other to form a ring; and
p and q are each independently an integer of 1 to 5.
   The sulfur-containing siloxane in the present disclosure may not include a compound of the formula (1) wherein A¹ to A⁷ and A¹⁰ are a methyl group; A⁸ and A⁹ are a trimethylsiloxy group; and p and q are 1.

A¹ to A¹⁰, at each occurrence, are each independently a hydrogen atom, an organic group, a halogen, a siloxy group represented by OSiR^{a}R^{b}R^{c}, or an amino group represented by NR^{d}R^{e}. However, A¹ and A³ optionally become one to be an oxygen atom to thereby form a cyclic siloxane (that is, -A¹-A³- may be —O—), and A⁴ and A⁶ optionally become one to be an oxygen atom to thereby form a cyclic siloxane (that is, -A⁴-A⁶- may be —O—). Either A¹ and A³ or A⁴ and A⁶ optionally form a cyclic siloxane.

The percentage by number of groups other than a hydrogen atom (for example, organic groups, particularly monovalent aliphatic hydrocarbon groups) in all of A¹ to A¹⁰ may be 0% or more, 10% or more, 30% or more, 50% or more, or 70% or more and it is, for example, 50% or more, or for example, 100%. The percentage by number of groups other than a hydrogen atom (for example, organic groups, particularly monovalent aliphatic hydrocarbon groups) in all of A¹ to A¹⁰ may be 90% or less, 70% or less, 50% or less, 30% or less, or 0%. Each —Si may have zero or at least one (one, two or three) groups other than a hydrogen atom (for example, organic groups, particularly monovalent aliphatic hydrocarbon groups).

At least one (for example, 1 or more, or two or more) among all of A¹ to A¹⁰ may be a hydrogen atom. For example, at least one (for example, either one or both) of A² and A¹⁰ in each —SiA²A¹⁰O— may be a hydrogen atom, and at least one (for example, either one or both) of A⁵ and A⁷ in each —SiA⁵A⁷O— may be a hydrogen atom. For example, each Si may be bonded to at least one hydrogen atom.

Each of A² and A¹⁰ may be the same as or different from each other, and each of A⁵ and A⁷ may be the same as or different from each other. Each of A¹ to A¹⁰ may be the same as or different from each other. Each of A², A⁵ and A⁷ to A¹⁰ be the same as or different from each other.

The organic group of each of A¹ to A¹⁰ may be an aliphatic group or an aromatic group, and is preferably an aliphatic group (for example, an aliphatic hydrocarbon group). The organic group of each of A¹ to A¹⁰ may be a hetero atom-containing group or a hydrocarbon group, and is preferably a hydrocarbon group (for example, an aliphatic hydrocarbon group). The organic group of each of A¹ to A¹⁰ may be linear, branched or cyclic, and is preferably linear. The number of carbon atoms in the organic group of each of A¹ to A¹⁰ may be 1 or more, 2 or more, 3 or more, 5 or more, or 7 or more. The number of carbon atoms in the organic group of each of A¹ to A¹⁰ may be 20 or less, 15 or less, 10 or less, 5 or less, or 3 or less, and is preferably 5 or less.

R^{a} to R^{e} in OSiR^{a}R^{b}R^{c} or NR^{d}R^{e}, at each occurrence, are each independently a hydrogen atom, or an organic group. R^{d} and R^{e} are optionally combined with each other to form a ring.

The organic group of each of R^{a} to R^{e} may be an aliphatic group or an aromatic group, and is preferably aliphatic group (for example, an aliphatic hydrocarbon group). The organic group of each of R^{a} to R^{e} may be a hetero atom-containing group or a hydrocarbon group, and is preferably a hydrocarbon group (for example, an aliphatic hydrocarbon group). The organic group of each of R^{a} to R^{e} may be linear, branched or cyclic, and is preferably linear. The number of carbon atoms in the organic group of each of R^{a} to R^{e} may be 1 or more, 2 or more, 3 or more, 5 or more, or 7 or more. The number of carbon atoms in the organic group of each of R^{a} to R^{e} may be 20 or less, 15 or less, 10 or less, 5 or less, or 3 or less, and is preferably 5 or less.

For example, A¹ to A¹⁰, at each occurrence, may be each independently a hydrogen atom; an alkyl group having 1 to 10 carbon atoms (such as methyl, ethyl, propyl, isopropyl, n-butyl, sec-butyl, isobutyl, tert-butyl, pentyl, hexyl, heptyl, octyl, nonyl or decanyl); an alkenyl group having 2 to 10 carbon atoms (such as vinyl or 2-propenyl); an alkynyl group having 2 to 10 carbon atoms (such as ethynyl or propynyl); a cycloalkyl group having 3 to 10 carbon atoms (such as cyclopentyl or cyclobutyl); an aryl group having 4 to 10 carbon atoms (such as cyclopentadienyl or phenyl); a halogen atom (such as a fluorine atom, a chlorine atom, a bromine atom, or an iodine atom); a siloxy group represented by OSiR^{a}R^{b}R^{c} (such as trimethylsiloxy or dimethylsiloxy); or an amino group represented by NR^{d}R^{e} (such as methylamino, ethylamino, dimethylamino, diethylamino, propylamino, isopropylamino, dipropylamino, diisopropylamino, pyrrolidino or piperidino). Preferably, they are a hydrogen atom, or an alkyl group having 1 to 3 carbon atoms (such as methyl, ethyl, propyl or isopropyl). A¹ and A³ optionally become one to be an oxygen atom to thereby form a cyclic siloxane, and A⁴ and A⁶ optionally become one to be an oxygen atom to thereby form a cyclic siloxane. The hydrocarbon group of each of A¹ to A¹⁰ may be each independently branched or liner, and is preferably linear.

p and q in the formula (1) are each an integer selected from 1 to 5. For example, (p, q) is (1, 1), (2, 2), (3, 3), (4, 4), (5, 5), (1, 2) or (4, 5).

The sulfur-containing siloxane may have a molecular weight of 200 or more, 250 or more, 300 or more, or 350 or more. The sulfur-containing siloxane may have a molecular weight of 1,000 or less, 900 or less, 800 or less, or 700 or less, and it preferably has a molecular weight of 700 or less.

The sulfur-containing siloxane may have 0 carbon atoms or more, 1 carbon atom or more, 5 carbon atoms or more, 10 carbon atoms or more, 15 carbon atoms or more, 20 carbon atoms or more, 25 carbon atoms or more, or 30 or carbon atoms or more. The sulfur-containing siloxane may have 50 carbon atoms or less, 45 carbon atoms or less, 40 carbon atoms or less, 35 carbon atoms or less, 30 carbon atoms or less, or 25 carbon atoms or less.

The presence of a larger number of Si—O structures in one molecule is preferable in view of the properties of the film, because the constituent elements are similar to that of film composition when forming a silicon oxide film. Although the detailed reason therefor is not clear, the presence of the Si—S structures is preferable in view of a method for forming a film under high temperature conditions. On the other hand, the molecular size is also important, in view of film formability and vapor pressure control. After diligent research, the present inventors have found that a good effect can be provided by using the sulfur-containing siloxane having such an appropriate number of Si—O structures and such an appropriate molecular weight as specified above.

### [Cyclic Siloxane]

The sulfur-containing siloxane in the present disclosure may be cyclic siloxane. For example, the sulfur-containing siloxane in the present disclosure may be a bis(cyclotrisiloxanyl)sulfide compound, a bis(cyclotetrasiloxanyl)sulfide compound, a bis(cyclopentasiloxanyl)sulfide compound, a bis(cyclohexasiloxanyl)sulfide compound, a (cyclotrisiloxanyl)thiocyclotetrasiloxane compound, a (cyclotrisiloxanyl)thiocyclopentasiloxane compound, a (cyclotrisiloxanyl)thiocyclohexasiloxane compound, a (cyclotetrasiloxanyl)thiocyclopentasiloxane compound, a (cyclotetrasiloxanyl)thiocyclohexasiloxane compound, or a (cyclopentasiloxanyl)thiocyclohexasiloxane compound.

The sulfur-containing siloxane in the present disclosure may be particularly a sulfur-containing siloxane which is a cyclic siloxane represented by the following formula (2):

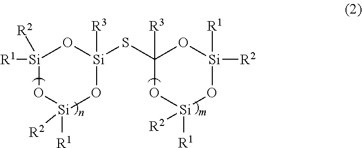

wherein, in the formula (2),
R¹ to R³, at each occurrence, are each independently a hydrogen atom, or a monovalent aliphatic hydrocarbon group having 1 to 10 carbon atoms; and
n and m are each independently an integer of 1 to 4.

In the formula (2), R¹ to R³, at each occurrence, are each independently a hydrogen atom; a monovalent aliphatic hydrocarbon group having 1 to 10 carbon atoms (such as a alkyl group having 1 to 10 carbon atoms (such as methyl, ethyl, propyl, isopropyl, n-butyl, sec-butyl, isobutyl, tert-butyl, pentyl, hexyl, heptyl, octyl, nonyl or decanyl); an alkenyl group having 2 to 10 carbon atoms (such as vinyl or 2-propenyl); or an alkynyl group having 2 to 10 carbon atoms (such as ethynyl or propynyl), and preferably a hydrogen atom, or an alkyl group having 1 to 3 carbon atoms (methyl, ethyl, propyl or isopropyl)). The hydrocarbon group in R¹ to R³, at each occurrence, may be each independently branched or linear and is preferably linear.

In the formula (2), the percentage by number of groups other than a hydrogen atom (monovalent aliphatic hydrocarbon groups) in all of R¹ to R³ may be 0% or more, 10% or more, 30% or more, 50% or more, or 70% or more and it is, for example, 50% or more, or for example, 100%. The percentage by number of groups other than a hydrogen atom (monovalent aliphatic hydrocarbon groups) in all of R¹ to R³ may be 90% or less, 70% or less, 50% or less, 30% or less, or 0%. Each —Si may have zero or one or more (for example, one or two) groups other than a hydrogen atom (monovalent aliphatic hydrocarbon groups).

In the sulfur-containing siloxane of the formula (2), at least one (for example, 1 or more, or two or more) among all of R¹ and R² may be a hydrogen atom. At least one (for example, either one or both) of R¹ and R² in each —SiR¹R²O— may be a hydrogen atom.

In the formula (2), each of R¹ and R² may be the same as or different from each other, and each of R¹ to R³ may be the same as or different from each other.

In the formula (2), n and m are each an integer selected from 1 to 4, and for example, n=m=2. When p, q, n and m are within the above ranges, the sulfur-containing siloxane can be excellent in film formability. For example, the sulfur-containing siloxane may be a compound represented by the following formula (3), in which n and m are each 2:

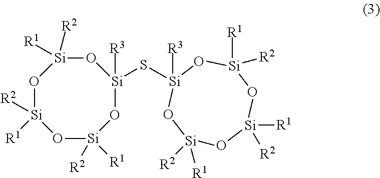

wherein, in the formula (3),
R¹ to R³, at each occurrence, are each independently a hydrogen atom, or a monovalent aliphatic hydrocarbon group having 1 to 10 carbon atoms.

Examples of the sulfur-containing siloxane which is a cyclic siloxane include bis(cyclotrisiloxanyl)sulfide, bis(2,4,6-trimethylcyclotrisiloxanyl)sulfide, bis(2,4,6-triethylcyclotrisiloxanyl)sulfide, bis(2,4,4,6,6-pentamethylcyclotrisiloxanyl)sulfide, bis(2,4,4,6,6-pentaethylcyclotrisiloxanyl)sulfide, bis(2,4,4,6,6-pentaphenylcyclotrisiloxanyl)sulfide, bis(cyclotetrasiloxanyl)sulfide, bis(2,4,6,8-tetramethylcyclotetrasiloxanyl) sulfide, bis(2,4,6,8-tetraethylcyclotetrasiloxanyl)sulfide, bis(2,4,4,6,6,8,8-heptamethylcyclotetrasiloxanyl)sulfide, bis(2,4,4,6,6,8,8-heptaethylcyclotetrasiloxanyl)sulfide, bis(2,4,4,6,6,8,8-heptaphenylcyclotetrasiloxanyl)sulfide, bis(cyclopentasiloxanyl)sulfide, bis(2,4,6,8,10-pentamethylcyclopentasiloxanyl)sulfide, bis(2,4,6,8,10-pentaethylcyclopentasiloxanyl)sulfide, bis(2,4,4,6,6,8,8,10,10-nonamethylcyclopentasiloxanyl)sulfide, bis(2,4,4,6,6,8,8,10,10-nonaethylcyclopentasiloxanyl)sulfide, bis(2,4,4,6,6,8,8,10,10-nonaphenylcyclopentasiloxanyl)sulfide, bis(cyclohexasiloxanyl)sulfide, bis(2,4,6,8,10,12-hexamethylcyclohexasiloxanyl)sulfide, bis(2,4,6,8,10,12-hexaethylcyclohexasiloxanyl)sulfide, bis(2,4,4,6,6,8,8,10,10,12,12-undecamethylcyclohexasiloxanyl)sulfide, bis(2,4,4,6,6,8,8,10,10,12,12-undecaethylcyclohexasiloxanyl)sulfide, bis(2,4,4,6,6,8,8,10,10,12,12-undecaphenylcyclohexasiloxanyl)sulfide, 2-[(2′,4′,6′-trimethylcyclotrisiloxan-2′-yl)thio]-2,4,6,8-tetramethylcyclotetrasiloxane, 2-[(2′,4′,6′-trimethylcyclotrisiloxan-2′-yl)thio]-2,4,6,8,10-pentamethylcyclopentasiloxane, 2-[(2′,4′,6′-trimethylcyclotrisiloxan-2′-yl)thio]-2,4,6,8,10,12-hexamethylcyclohexasiloxane, 2-[(2′,4′,6′,8′-tetramethylcyclotetrasiloxan-2′-yl)thio]-2,4,6,8,10-pentamethylcyclopentasiloxane, 2-[(2′,4′,6′,8′-tetramethylcyclotetrasiloxan-2′-yl)thio]-2,4,6,8,10,12-hexamethylcyclohexasiloxane, and 2-[(2′,4′,6′,8′,10′-pentamethylcyclopentasiloxan-2′-yl)thio]-2,4,6,8,10,12-hexamethylcyclohexasiloxane.

The sulfur-containing siloxane in the present disclosure may be bis(2,4,6,8-tetramethylcyclotetrasiloxanyl)sulfide, which is represented by the following formula (4):

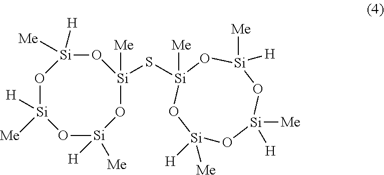 [SMILES: C[SiH]1O[SiH](C)O[Si](C)(S[Si]2(C)O[SiH](C)O[SiH](C)O[SiH](C)O2)O[SiH](C)O1]

### [Noncyclic Siloxane]

The sulfur-containing siloxane in the present disclosure may be noncyclic siloxane. For example, the sulfur-containing siloxane in the present disclosure may be a bis(disiloxanyl)sulfide compound, a bis(trisiloxanyl)sulfide compound, a bis(tetrasiloxanyl)sulfide compound, a bis(pentasiloxanyl)sulfide compound, a (disiloxanyl)thiotrisiloxane compound, a (disiloxanyl)thiotetrasiloxane compound, a (disiloxanyl)thiopentasiloxane compound, a (trisiloxanyl)thiotetrasiloxane compound, a (trisiloxanyl)thiopentasiloxane compound, or a (tetrasiloxanyl)thiopentasiloxane compound.

The sulfur-containing siloxane in the present disclosure may be particularly a sulfur-containing siloxane which is a noncyclic siloxane represented by the following formula (5):

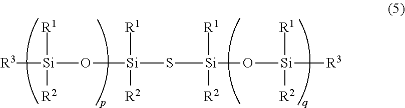

wherein, in the formula (5),
R¹ to R³, at each occurrence, are each independently a hydrogen atom, or a monovalent aliphatic hydrocarbon group having 1 to 10 carbon atoms; and
p and q are each independently an integer of 1 to 5.

In the formula (5), R¹ to R³, at each occurrence, are each independently a hydrogen atom; a monovalent aliphatic hydrocarbon group having 1 to 10 carbon atoms (such as a alkyl group having 1 to 10 carbon atoms (such as methyl, ethyl, propyl, isopropyl, n-butyl, sec-butyl, isobutyl, tert-butyl, pentyl, hexyl, heptyl, octyl, nonyl or decanyl); an alkenyl group having 2 to 10 carbon atoms (such as vinyl or 2-propenyl); or an alkynyl group having 2 to 10 carbon atoms (such as ethynyl or propynyl), and preferably a hydrogen atom, or an alkyl group having 1 to 3 carbon atoms (methyl, ethyl, propyl or isopropyl)). The hydrocarbon group in R¹ to R³, at each occurrence, may be each independently branched or linear and is preferably linear.

In the formula (5), the percentage by number of groups other than a hydrogen atom (monovalent aliphatic hydrocarbon groups) in all of R¹ to R³ may be 0% or more, 10% or more, 30% or more, 50% or more, or 70% or more and it is, for example, 50% or more, or for example, 100%. The percentage by number of groups other than a hydrogen atom (monovalent aliphatic hydrocarbon groups) in all of R¹ to R³ may be 90% or less, 70% or less, 50% or less, 30% or less, or 0%. Each —Si may have zero, or one or more (for example, one or two) groups other than a hydrogen atom (monovalent aliphatic hydrocarbon groups).

In the sulfur-containing siloxane of the formula (5), at least one (for example, 1 or more, or two or more) among all of R¹ and R² may be a hydrogen atom, but the sulfur-containing siloxane preferably has a plurality of monovalent aliphatic hydrocarbon groups. At least one (for example, either one or both) of R¹ and R² in each —SiR¹R²O— may be a monovalent aliphatic hydrocarbon group, or all of R¹ to R³ may be each a monovalent aliphatic hydrocarbon group.

In the formula (5), each of R¹ and R² may be the same as or different from each other, and each of R¹ to R³ may be the same as or different from each other.

p and q in the formula (5) are each independently an integer selected from 1 to 5. For example, (p, q) is (1, 1), (2, 2), (3, 3), (4, 4), (5, 5), (1, 2) or (4, 5). For example, the sulfur-containing siloxane may be a compound represented by the following formula (6), in which p and q are each 1:

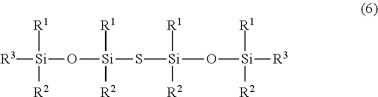

wherein, in the formula (6),
R¹ to R¹⁰, at each occurrence, are each independently a hydrogen atom, or a monovalent aliphatic hydrocarbon group having 1 to 10 carbon atoms.

Examples of the sulfur-containing siloxane which is a noncyclic siloxane include bis(disiloxanyl)sulfide, bis(1,1,3,3-tetramethyldisiloxanyl)sulfide, bis(1,1,3,3-tetraethyldisiloxanyl)sulfide, bis(1,1,3,3-tetrapropyldisiloxanyl)sulfide, bis(1,1,3,3-tetraisopropyldisiloxanyl)sulfide, bis(1,1,1,3,3-pentamethyldisiloxanyl)sulfide, bis(1,1,1,3,3-pentaethyldisiloxanyl)sulfide, bis(1,1,1,3,3-pentapropyldisiloxanyl)sulfide, bis(1,1,1,3,3-pentaisopropyldisiloxanyl)sulfide, bis(trisiloxanyl)sulfide, bis(1,1,3,3,5,5-hexamethyltrisiloxanyl)sulfide, bis(1,1,3,3,5,5-hexaethyltrisiloxanyl)sulfide, bis(1,1,3,3,5,5-hexapropyltrisiloxanyl)sulfide, bis(1,1,3,3,5,5-hexaisopropyltrisiloxanyl)sulfide, bis(1,1,1,3,3,5,5-heptamethyltrisiloxanyl)sulfide, bis(1,1,1,3,3,5,5-heptaethyltrisiloxanyl)sulfide, bis(1,1,1,3,3,5,5-heptapropyltrisiloxanyl)sulfide, bis(1,1,1,3,3,5,5-heptaisopropyltrisiloxanyl)sulfide, (disiloxanyl)thiotrisiloxane, (1,1,3,3-tetramethyldisiloxanyl)thiotrisiloxane, (1,1,3,3-tetraethyldisiloxanyl)thiotrisiloxane, (1,1,1,3,3-pentamethyldisiloxanyl)thiotrisiloxane, (1,1,1,3,3-pentaethyldisiloxanyl)thiotrisiloxane, (1,1,3,3-tetramethyldisiloxanyl)thio-1,1,3,3,5,5,5-pentamethyltrisiloxane, (1,1,3,3-tetraethyldisiloxanyl)thio-1,1,3,3,5,5,5-pentamethyltrisiloxane, (1,1,1,3,3-pentamethyldisiloxanyl)thio-1,1,3,3,5,5,5-pentamethyltrisiloxane, and (1,1,1,3,3-pentaethyldisiloxanyl)thio-1,1,3,3,5,5,5-pentamethyltrisiloxane.

The sulfur-containing siloxane in the present disclosure may be bis(1,1,1,3,3-pentamethyldisiloxan-3-yl)sulfide, which is represented by the following formula (7)

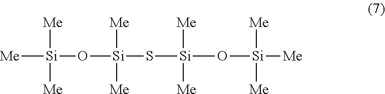 [SMILES: C[Si](C)(C)O[Si](C)(C)S[Si](C)(C)O[Si](C)(C)C]

### <Method for Producing Sulfur-Containing Siloxane>

The method for producing a sulfur-containing siloxane in the present disclosure may include a production method comprising:
(a) the step of synthesizing a sulfur-containing siloxane from a raw material siloxane; and
(b) the distillation step of isolating the sulfur-containing siloxane by distillation.
   [Synthesis Step (a)]

The synthesis step (a) may comprise the step of reacting the raw material siloxane with a sulfurizing agent.

The raw material siloxane may be compounds represented the following formulas (8-1) and (8-2):

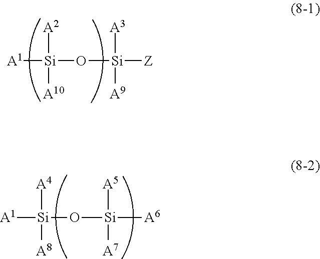

wherein, in the formulas (8-1) and (8-2),
A¹ to A¹⁰, at each occurrence, are each independently a hydrogen atom, an organic group, a halogen, a siloxy group represented by OSiR^{a}R^{b}R^{c}, or an amino group represented by NR^{d}R^{e}; provided that A¹ and A³ optionally become one to be an oxygen atom to thereby form a cyclic siloxane, and provided that A⁴ and A⁶ optionally become one to be an oxygen atom to thereby form a cyclic siloxane;
R^{a} to R^{e}, at each occurrence, are each independently a hydrogen atom, or an organic group, and R^{d} and R^{e} are optionally combined with each other to form a ring;
p and q are each independently an integer of 1 to 5; and
Z is a halogen or a hydrogen atom. Here, the modes of A¹ to A¹⁰ and p and q are as described above.

The raw material siloxane may be a compound represented by the following formula (8-3):

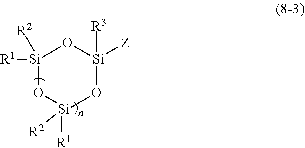

wherein, in the formula (8-3),
R¹ to R³, at each occurrence, are each independently a hydrogen atom, or a monovalent aliphatic hydrocarbon group having 1 to 10 carbon atoms;
Z is a halogen or a hydrogen atom; and
n is an integer of 1 to 4. Herein, the modes of R¹, R², R³ and n are as described above.

The raw material siloxane may be a compound represented by the following formula (8-4):

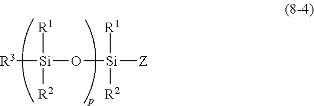

wherein, in the formula (8-4),
R¹ to R³, at each occurrence, are each independently a hydrogen atom, or a monovalent aliphatic hydrocarbon group having 1 to 10 carbon atoms;
Z is a halogen or a hydrogen atom; and
p is an integer of 1 to 5. Here, the modes of R¹ to R³, p and q are as described above.

Examples of Z include a fluorine atom, a chlorine atom, a bromine atom, an iodine atom, and a hydrogen atom.

The raw material siloxane may have a molecular weight of 100 or more, 150 or more, 200 or more, or 250 or more. The raw material siloxane may have a molecular weight of 750 or less, 600 or less, 500 or less, or 400 or less, and it preferably has a molecular weight of 500 or less.

The raw material siloxane may have 0 carbon atoms or more, 1 carbon atom or more, 3 carbon atoms or more, 5 carbon atoms or more, 7 carbon atoms or more, 10 carbon atoms or more, 12 carbon atoms or more, or 15 carbon atoms or more. The raw material siloxane may have 30 carbon atoms or less, 25 carbon atoms or less, 20 carbon atoms or less, 15 carbon atoms or less, or 10 carbon atoms or less.

The raw material siloxane may be previously synthesized and then used. For example, a siloxane compound wherein Z is a hydrogen atom may be used as it is in the synthesis step (a), or Z in the siloxane compound may be replaced with a halogen using a halogenating agent, followed by the synthesis step (a). The halogenating agent may be a fluorinating agent, a chlorinating agent, a brominating agent, or an iodinating agent. Among them, a chlorinating agent such as N-chlorosuccinimide or N-chlorophthalimide is preferably used.

The sulfurizing agent is a sulfur compound that can be used to replace Z in —SiZ with sulfur, and examples of the sulfurizing agent that can be used include sulfides such as lithium sulfide, sodium sulfide and hydrogen sulfide.

An example of the reaction formula between the raw material siloxanes (8-1) and (8-2) and the sulfurizing agent is shown below.

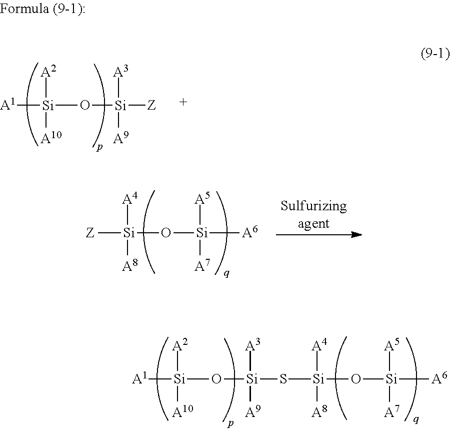

An example of the reaction formula between the raw material siloxane (8-3) and the sulfurizing agent is shown below.

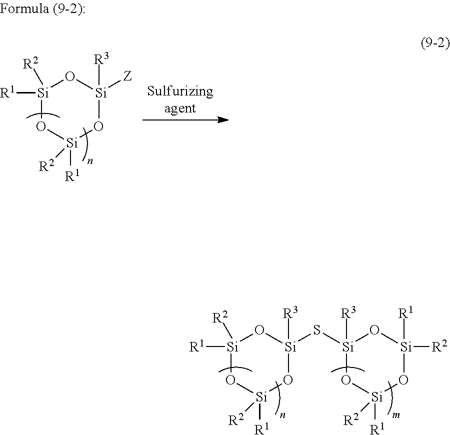

An example of the reaction formula between the raw material siloxane (8-4) and the sulfurizing agent is shown below.

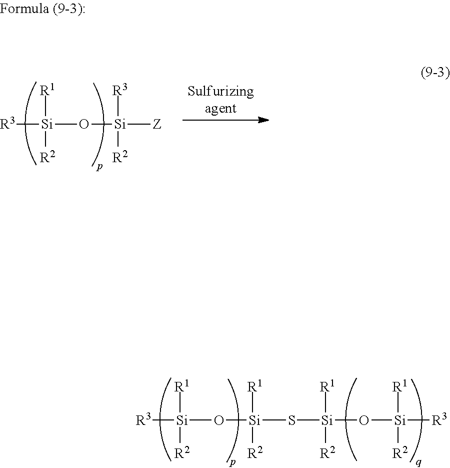

To the present reaction in the step (a), it is possible to apply either of a method including first dissolving a raw material siloxane in an organic solvent and then adding a sulfurizing agent thereto, or a method including dissolving a sulfurizing agent in an organic solvent and then adding a raw material siloxane thereto.

The amount of the sulfurizing agent to be used is usually 0.2 to 3.0 moles, preferably 0.4 to 2.0 moles (such as 0.5 to 1.0 mole) per 1.0 mole of the raw material siloxane.

The reaction may be performed at a temperature in the range of −20° C. to 100° C., preferably −10° C. to 60° C. The reaction time usually ranges from 0.5 to 30 hours.

Examples of the solvent that can be used in the present disclosure include: hydrocarbons such as hexane, cyclohexane, heptane, nonane and decane; halogenated hydrocarbons such as dichloroethane, dichloromethane and chloroform; aromatic hydrocarbons such as benzene, toluene, xylene, chlorobenzene and trichlorobenzene; ethers such as diethyl ether, tetrahydrofuran (THF) and ethylene glycol dimethyl ether; and a mixture thereof. Among these, ethers such as diethyl ether and tetrahydrofuran (THF) are preferred, and, particularly, tetrahydrofuran (THF) is preferably used. The amount of the solvent to be used is usually 0.1 to 50 times the mass of the raw material siloxane compound.

In order to avoid hydrolysis of the siloxane and the sulfur-containing siloxane, all the reaction system is desirably performed under anhydrous conditions, and the reaction is performed under a condition of the water content in all raw materials to be used in the range of 0 to 5,000 ppm by mass, preferably 0 to 500 ppm by mass relative to the mass of all raw materials. It is desirable to use a reactor that has been dried by heating under reduced pressure, or by purging with an inert gas such as nitrogen or argon.

In the step (a), if solids such as salts as by-products are present in a reaction liquid, filtration may be optionally performed after the reaction is completed. If filtration is performed, it is desirably performed under a dried inert gas such as nitrogen or argon to suppress decomposition of the sulfur-containing siloxane. Although the filtration temperature is not uniquely determined, a temperature from 10° C. to the boiling point of the solvent to be used can be applied. It is desirable that the filtration should be performed preferably at a temperature in the range of 20° C. to 65° C.

[Distillation Step (b)]

In the step (b), distillation such as distillation under reduced pressure is performed to isolate the sulfur-containing siloxane. The sulfurizing agent and the organic solvent can be easily removed to purify the sulfur-containing siloxane to a sufficiently high purity.

### <Method for Producing Silicon-Containing Film>

The sulfur-containing siloxane according to the present disclosure can be used as an intermediate for a silicon-containing film to form a silicon-containing film on a substrate. The method for forming the silicon-containing film according to the present disclosure may be chemical vapor deposition, particularly atomic layer deposition. More particularly, the method for forming the silicon-containing film according to the present disclosure may be an atomic layer deposition method comprising:
(c) the step of contacting, with a substrate, a sulfur-containing siloxane composition containing a sulfur-containing siloxane represented by the following formula (1):

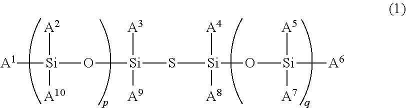

wherein, in the formula (1),
A¹ to A¹⁰, at each occurrence, are each independently a hydrogen atom, an organic group, a halogen, a siloxy group represented by OSiR^{a}R^{b}R^{c}, or an amino group represented by NR^{d}R^{e}; provided that A¹ and A³ optionally become one to be an oxygen atom to thereby form a cyclic siloxane, and provided that A⁴ and A⁶ optionally become one to be an oxygen atom to thereby form a cyclic siloxane;
R^{a} to R^{e}, at each occurrence, are each independently a hydrogen atom, or an organic group, and R^{d} and R^{e} are optionally combined with each other to form a ring; and
p and q are each independently an integer of 1 to 5, to adsorb the sulfur-containing siloxane composition on the substrate;
(d) the step of purging an unadsorbed sulfur-containing siloxane composition and by-products;
(e) the step of injecting a reaction gas into the substrate on which the sulfur-containing siloxane composition has been adsorbed, thereby decomposing the sulfur-containing siloxane to form an atomic layer; and
(f) the step of purging an unreacted reaction gas and by-products.

The substrate temperature may be 100 to 800° C., preferably 100 to 750° C. In view of the properties of a film to be obtained, the substrate temperature may be 200° C. or more, 300° C. or more, 400° C. or more, 500° C. or more, 600° C. or more, or 700° C. or more, and it is for example 250° C. or more and preferably 300° C. or more, 400° C. or more, or 500° C. or more. The film forming temperature may be the temperature in at least one of the steps (c) to (f), for example, the temperature of the substrate when contacted with the sulfur-containing siloxane composition in the step (c). The silicon-containing film obtained from the sulfur-containing siloxane of the present disclosure is stable even at high temperatures. The sulfur-containing siloxane of the present disclosure can also be suitably used for a method for producing a silicon-containing film in which a high substrate temperature is used.

The pressure during gas injection in the step (c) and (e) is 0.05 to 100 Torr, preferably 0.05 to 50 Torr.

In the step (e), when forming a silicon oxide film having a Si—O bond, one or more gases selected from oxygen, ozone and nitrogen monooxide can be used as a reaction gas. When forming a silicon nitride film having a Si—N bond, one or more gases selected from nitrogen, ammonia, dinitrogen monooxide, nitrogen monooxide and nitrogen dioxide can be used.

The silicon-containing film is desirably formed after purging with an inert gas such as nitrogen or argon. That is, the step (c) is preferably performed after purging the interior of the reaction system with an inert gas.

The sulfur-containing siloxane of the present disclosure is suitably used for the production of a silicon-containing film (such as a silicon oxide film or a silicon nitride film) by an ALD method. In the method for producing a silicon-containing film in the present disclosure, the lower limit of the ALD window may be 300° C. and is preferably 350° C. In the method for producing a silicon-containing film in the present disclosure, the upper limit of the ALD window may be 800° C. and is preferably 750° C. The ALD window as used herein generally refers to the temperature range between the vaporization temperature of a silicon-containing film precursor compound and the thermal decomposition temperature of the silicon-containing film precursor compound. In the present specification, the ALD window can be defined as the temperature range from the point at which the deposition rate is maximum to the point at which the deposition rate is minimum, when the horizontal axis and the vertical axis are the film formation temperature and the deposition rate, respectively.

### EXAMPLES

Hereinafter, the present disclosure will be described in more detail by way of Examples thereof.

### Example 1: Synthesis of bis(2,4,6,8-tetramethylcyclotetrasiloxanyl)sulfide

After nitrogen purge, 7.7 g (0.17 moles) of lithium sulfide and 82.1 g of tetrahydrofuran were placed in a 500 mL flask equipped with a thermometer, a condenser tube and a motor stirrer. While stirring at room temperature, 145.9 g of a solution containing 72.6 g (0.26 moles) of 2-chloro-2,4,6,8-tetramethylcyclotetrasiloxane was slowly added dropwise thereto over 30 minutes. After adding it dropwise, the mixture was stirred for 23 hours while maintaining the temperature in the range of 26 to 33° C. Thereafter, in a glove box the interior of which had been purged with nitrogen, solids including mainly lithium chloride as a by-product were removed by filtration under reduced pressure to obtain a solution containing bis(2,4,6,8-tetramethylcyclotetrasiloxanyl)sulfide in tetrahydrofuran. This solution in tetrahydrofuran was distilled under reduced pressure at an internal temperature of 60 to 80° C. to remove tetrahydrofuran, and was further distilled under reduced pressure using a distillation column at an internal temperature of 145° C. and a pressure of 0.6 Torr to obtain bis(2,4,6,8-tetramethylcyclotetrasiloxanyl)sulfide in high purity.

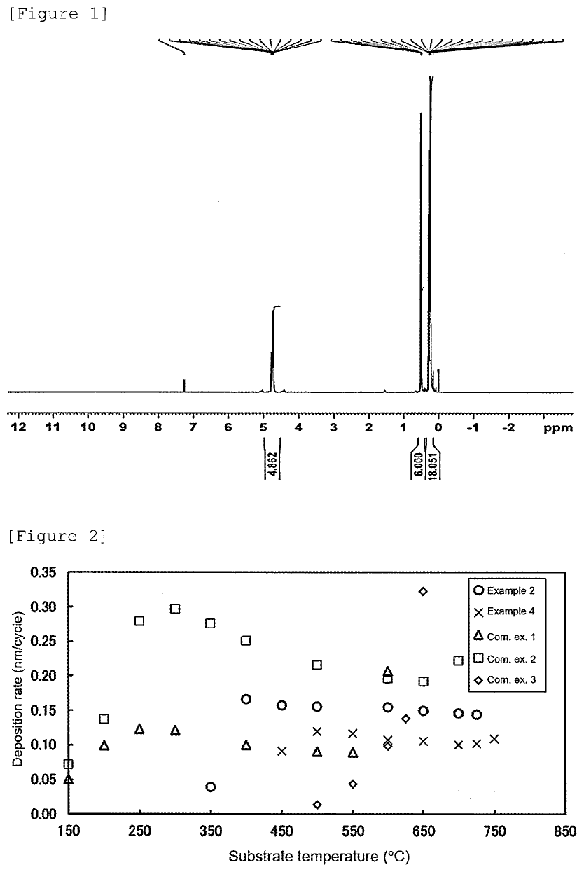

It was confirmed by GC analysis after distillation that 19.0 g (yield: 28.1%) of bis(2,4,6,8-tetramethylcyclotetrasiloxanyl) sulfide was obtained with a purity of 96.2% by area. The obtained bis(2,4,6,8-tetramethylcyclotetrasiloxanyl) sulfide was identified by ¹H-NMR and GC-MS. The ¹H-NMR assignment is as follows. The ¹H-NMR chart is as shown in FIG. 1.

¹H-NMR (400 MHz, CDCl₃): δ0.21-0.28 (m, 18H, [CH₃—SiH—]), δ0.48-0.51, 6H, [CH₃—SiS]), δ4.71-4.79 (m, 6H, [Si—H])

From the results of the above 1H-NMR and GC-MS, the obtained sulfur-containing siloxane was identified to be bis(2,4,6,8-tetramethylcyclotetrasiloxanyl)sulfide represented by the following formula:

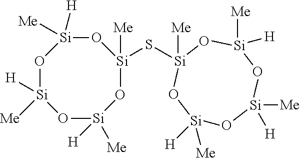 [SMILES: C[SiH]1O[SiH](C)O[Si](C)(S[Si]2(C)O[SiH](C)O[SiH](C)O[SiH](C)O2)O[SiH](C)O1]

### Example 2: Formation of Silicon-Containing Film by Using bis(2,4,6,8-tetramethylcyclotetrasiloxanyl)sulfide

A silicon substrate was placed in a vacuum device and heated to a predetermined temperature of 100 to 750° C. A siloxane composition containing the bis(2,4,6,8-tetramethylcyclotetrasiloxanyl)sulfide obtained in Example 1 and a carrier gas was injected at a pressure of 0.05 to 100 Torr to adsorb it onto the heated silicon substrate. Then, an argon gas was introduced in the device to purge an unadsorbed sulfur-containing siloxane composition and by-products from the device. Thereafter, ozone was injected as a reaction gas at a pressure of 0.05 to 100 Torr to form an atomic layer of the silicon oxide derived from the bis(2,4,6,8-tetramethylcyclotetrasiloxanyl)sulfide deposited on the substrate. Then, an argon gas was introduced to purge unreacted ozone and by-products. The above cycle was repeated to obtain a silicon oxide film.

### Example 3: Synthesis of bis(1,1,1,3,3-pentamethyldisiloxan-3-yl)sulfide

After nitrogen purge, 274 g (1.85 moles) of pentamethyldisiloxane and 1,700 g of tetrahydrofuran were placed in a 3 L flask equipped with a thermometer, a condenser tube and a motor stirrer. While stirring at room temperature, 244 g (1.83 moles) of N-chlorosuccinimide was added thereto. After adding it, the mixture was stirred for 5 hours while maintaining the temperature in the range of 56 to 59° C. Thereafter, it was distilled under reduced pressure at an internal temperature of 60 to 80° C. to remove tetrahydrofuran, and filtered under reduced pressure in a glove box the interior of which had been purged with nitrogen, thereby removing solids as by-products to obtain a solution containing chloropentamethyldisiloxane in tetrahydrofuran. This solution in tetrahydrofuran was further distilled under reduced pressure using a distillation column at an internal temperature of 100° C. and a pressure of 175 Torr to obtain a high-purity solution containing chloropentamethyldisiloxane in tetrahydrofuran. Subsequently, after nitrogen purge, 8.7 g (0.19 moles) of lithium sulfide and 96 g of tetrahydrofuran were placed in a 300 mL flask equipped with a thermometer, a condenser tube and a motor stirrer. While stirring at room temperature, a 68 g of the solution containing 56 g (0.31 moles) of chloropentamethyldisiloxane in tetrahydrofuran obtained earlier was slowly added dropwise over 40 minutes. After adding it dropwise, the mixture was stirred for 4 hours while maintaining the temperature in the range of 26 to 33° C. Thereafter, in a glove box the interior of which had been purged with nitrogen, solids including mainly lithium chloride as a by-product were removed by filtration under reduced pressure to obtain a solution containing bis(1,1,1,3,3-pentamethyldisiloxan-3-yl)sulfide in tetrahydrofuran. This solution in tetrahydrofuran was distilled under reduced pressure at an internal temperature of 60 to 80° C. to remove tetrahydrofuran, and was further distilled under reduced pressure using a distillation column at an internal temperature of 84° C. and a pressure of 2.2 Torr to obtain bis(1,1,1,3,3-pentamethyldisiloxan-3-yl)sulfide in high purity.

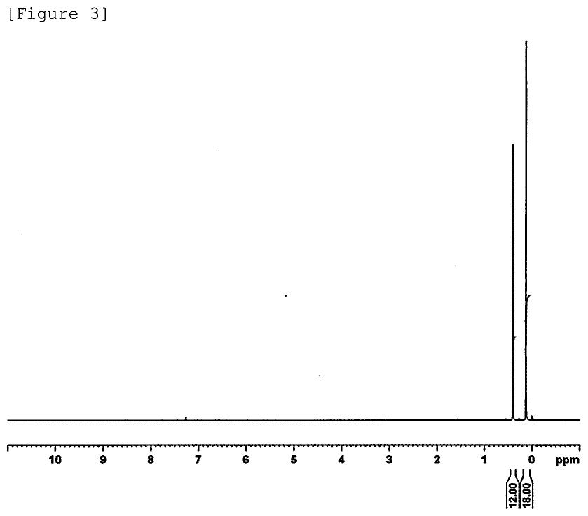

It was confirmed by GC analysis after distillation that 27 g (yield: 18%) of bis(1,1,1,3,3-pentamethyldisiloxan-3-yl)sulfide was obtained with a purity of 98.0% by area. The obtained bis(1,1,1,3,3-pentamethyldisiloxan-3-yl)sulfide was identified by ¹H-NMR and GC-MS. The ¹H-NMR assignment is as follows. The ¹H-NMR chart is as shown in FIG. 3.

¹H-NMR (400 MHz, CDCl₃): δ0.12 (s, 18H, [CH₃—Si]), δ0.40 (s, 12H, [CH₃—SiS])

From the results of the above ¹H-NMR and GC-MS, the obtained sulfur-containing siloxane was identified to be bis(1,1,1,3,3-pentamethyldisiloxan-3-yl)sulfide represented by the following formula:

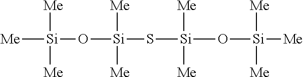 [SMILES: C[Si](C)(C)O[Si](C)(C)S[Si](C)(C)O[Si](C)(C)C]

### Example 4: Formation of Silicon-Containing Film by Using bis(1,1,1,3,3-pentamethyldisiloxan-3-yl)sulfide

A silicon substrate was placed in a vacuum device and heated to a predetermined temperature of 100 to 750° C. A siloxane composition containing the bis(1,1,1,3,3-pentamethyldisiloxan-3-yl)sulfide obtained in Example 3 and a carrier gas was injected at a pressure of 0.05 to 100 Torr to adsorb it onto the heated silicon substrate. Then, an argon gas was introduced in the device to purge an unadsorbed sulfur-containing siloxane composition and by-products from the device. Thereafter, ozone was injected as a reaction gas at a pressure of 0.05 to 100 Torr to form an atomic layer of the silicon oxide derived from the bis(1,1,1,3,3-pentamethyldisiloxan-3-yl) sulfide deposited on the substrate. Then, an argon gas was introduced to purge unreacted ozone and by-products. The above cycle was repeated to obtain a silicon oxide film.

### Comparative Example 1: Formation of Silicon-Containing Film by Using Bisdiethylaminosilane

A silicon substrate was placed in a vacuum device and heated to a predetermined temperature of 100 to 750° C. An aminosilane composition containing bisdiethylaminosilane and a carrier gas was injected at a pressure of 0.05 to 100 Torr to adsorb it onto the heated silicon substrate. Then, an argon gas was introduced in the device to purge an unadsorbed aminosilane composition and by-products from the device. Thereafter, ozone was injected as a reaction gas at a pressure of 0.05 to 100 Torr to form an atomic layer of the silicon oxide derived from the bisdiethylaminosilane deposited on the substrate. Then, an argon gas was introduced to purge an unreacted ozone gas and by-products. The above cycle was repeated to obtain a silicon oxide film.

### Comparative Example 2: Formation of Silicon-Containing Film by Using 2-dimethylamino-2,4,6,8-tetramethylcyclotetrasiloxane

A silicon substrate was placed in a vacuum device and heated to a predetermined temperature of 100 to 750° C. A siloxane composition containing 2-dimethylamino-2,4,6,8-tetramethylcyclotetrasiloxane and a carrier gas was injected at a pressure of 0.05 to 100 Torr to adsorb it onto the heated silicon substrate. Then, an argon gas was introduced in the device to purge an unadsorbed aminosiloxane composition and by-products from the device. Thereafter, ozone was injected as a reaction gas at a pressure of 0.05 to 100 Torr to form an atomic layer of the silicon oxide derived from the 2-dimethylamino-2,4,6,8-tetramethylcyclotetrasiloxane deposited on the substrate. Then, an argon gas was introduced to purge an unreacted ozone gas and by-products. The above cycle was repeated to obtain a silicon oxide film.

### Comparative Example 3: Formation of Silicon-Containing Film by Using triethoxy-[3-(trimethoxysilyl)propylthio]silane

A silicon substrate was placed in a vacuum device and heated to a predetermined temperature of 100 to 750° C. A siloxane composition containing triethoxy-[3-(trimethoxysilyl)propylthio]silane and a carrier gas was injected at a pressure of 0.05 to 100 Torr to adsorb it onto the heated silicon substrate. Then, an argon gas was introduced in the device to purge an unadsorbed aminosiloxane composition and by-products from the device. Thereafter, ozone was injected as a reaction gas at a pressure of 0.05 to 100 Torr to form an atomic layer of the silicon oxide derived from the triethoxy-[3-(trimethoxysilyl)propylthio]silane deposited on the substrate. Then, an argon gas was introduced to purge an unreacted ozone gas and by-products. The above cycle was repeated to obtain a silicon oxide film.

Table 1 below shows a specific vapor deposition method. FIG. 2 shows the relationship between the substrate temperature and the deposition rate. In the measurement for each plot in FIG. 2, the siloxane-supplying time that maximize the deposition rate was selected. Table 2 shows the deposition rate in Example 2 when 50 cycles were repeated at substrate temperatures of 400° C. and 725° C., which are the lowest and highest temperatures of the ALD window. Table 3 shows the deposition rate in Example 4 when 50 cycles were repeated at substrate temperatures of 500° C. and 750° C., which are the lowest and highest temperatures of the ALD window. The ALD window here refers to the temperature region from the point at which the deposition rate is maximum to the point at which the deposition rate is minimum in FIG. 2. Table 4 summarizes the temperature range of the ALD window for each of Example 2, Example 4, and Comparative Examples 1, 2 and 3. The layer thickness was measured with an ellipsometer.

TABLE 1

| | | |
|---|---|---|
| Raw material supply | 3-18 seconds | Supplied with Ar |
| Ar purge (1) | 25-60 seconds | 50-170 sccm |
| Ozone supply | 3 seconds | 100 sccm |
| Ar purge (2) | 30-45 seconds | 50-170 sccm |

TABLE 2

| Siloxane-supplying time | Deposition rate | Deposition rate |
|---|---|---|
| (second) | (nm/cycle) | (nm/cycle) |
| (Example 2) | (400° C.) | (725° C.) |
| 3 | — | 0.131 |
| 6 | — | 0.144 |
| 9 | 0.138 | 0.145 |
| 12 | 0.153 | — |
| 15 | 0.166 | — |
| 18 | 0.167 | — |

TABLE 3

| Siloxane-supplying time | Deposition rate | Deposition rate |
|---|---|---|
| (second) | (nm/cycle) | (nm/cycle) |
| (Example 4) | (500° C.) | (750° C.) |
| 6 | 0.116 | 0.109 |
| 9 | 0.116 | 0.110 |
| 12 | 0.116 | 0.112 |

TABLE 4

| | Example 2 | Comparative | Comparative | Example 4 | Comparative |
|---|---|---|---|---|---|
| | Bis(2,4,6,8- | Example 1 | Example 2 | Bis(1,1,1,3,3- | Example 3 |
| | tetramethylcyclo | Bisdiethyl | 2-Dimethylamino- | pentamethyl | Triethoxy-[3- |
| | tetrasiloxanyl) | amino- | 2,4,6,8-tetramethyl | disiloxan-3- | (trimethoxysilyl) |
| Compound | sulfide | silane | cyclotetrasiloxane | yl)sulfide | propylthio]silane |
| ALD | 400- | 250- | 300- | 500- | 550- |
| window | 725° C. | 550° C. | 650° C. | 750° C. | 600° C. |

As shown in Table 2, in Example 2, the supplying time of the bis(2,4,6,8-tetramethylcyclotetrasiloxanyl)sulfide composition was investigated in order to form an atomic layer of the silicon oxide derived from the bis(2,4,6,8-tetramethylcyclotetrasiloxanyl) sulfide compound. It was confirmed that the deposition rate reached its maximum in 15 seconds or more at a substrate temperature of 400° C., and in 6 seconds or more at a substrate temperature 725° C., and that ALD film formation was therefore possible at both temperatures.

As shown in Table 3, in Example 4, the supplying time of the bis(1,1,1,3,3-pentamethyldisiloxan-3-yl)sulfide composition was investigated in order to form an atomic layer of the silicon oxide derived from the bis(1,1,1,3,3-pentamethyldisiloxan-3-yl)sulfide compound. It was confirmed that the deposition rate reached its maximum in 6 seconds or more at a substrate temperature of 500° C., and in 6 seconds or more at a substrate temperature 750° C., and that ALD film formation was therefore possible at both temperatures.

As shown in Table 4 and FIG. 2, it was confirmed that the temperature region (ALD window) in which ALD film formation was possible was on the higher temperature side for bis(2,4,6,8-tetramethylcyclotetrasiloxanyl)sulfide and bis(1,1,1,3,3-pentamethyldisiloxan-3-yl)sulfide than for bisdiethylaminosilane, 2-dimethylamino-2,4,6,8-tetramethylcyclotetrasiloxane and triethoxy-[3-(trimethoxysilyl)propylthio]silane.

### INDUSTRIAL APPLICABILITY

Use of an atomic deposition method enables formation of an ultrathin silicon oxide film or the like having no atomic defect, even on a semiconductor substrate with high aspect ratio structures formed thereon, a nanowire, and the like. The sulfur-containing siloxane according to the present disclosure is useful in the atomic deposition method in which film formation is performed at a high temperature.

1. A sulfur-containing siloxane represented by the following formula (1): 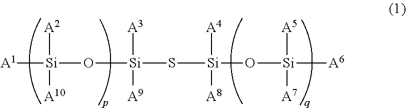
wherein, in the formula (1),
A¹ to A¹⁰, at each occurrence, are each independently a hydrogen atom, an organic group, a halogen, a siloxy group represented by OSiR^{a}R^{b}R^{c}, or an amino group represented by NR^{d}R^{e}; provided that A¹ and A³ optionally become one to be an oxygen atom to thereby form a cyclic siloxane, and provided that A⁴ and A⁶ optionally become one to be an oxygen atom to thereby form a cyclic siloxane;
R^{a} to R^{e}, at each occurrence, are each independently a hydrogen atom, or an organic group, and R^{d} and R^{e} are optionally combined with each other to form a ring; and
p and q are each independently an integer of 1 to 5.

2. The sulfur-containing siloxane according to claim 1, wherein A¹ and A³ become one to be an oxygen atom to thereby form a cyclic siloxane, and A⁴ and A⁶ become one to be an oxygen atom to thereby form a cyclic siloxane.

3. The sulfur-containing siloxane according to claim 1, which is represented by the following formula (2): 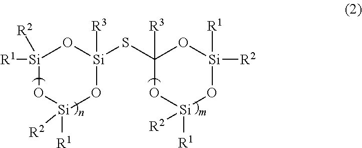
wherein, in the formula (2),
R¹ to R³, at each occurrence, are each independently a hydrogen atom, or a monovalent aliphatic hydrocarbon group having 1 to 10 carbon atoms; and
n and m are each independently an integer of 1 to 4.

4. The sulfur-containing siloxane according to claim 1, which has a molecular weight of 1,000 or less.

5. The sulfur-containing siloxane according to claim 1, wherein the sulfur-containing siloxane has 50 carbon atoms or less.

6. The sulfur-containing siloxane according to claim 1, which is represented by the following formula (3): 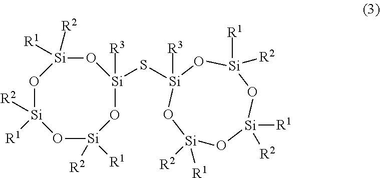
wherein, in the formula (3),
R¹ to R³, at each occurrence, are each independently a hydrogen atom, or a monovalent aliphatic hydrocarbon group having 1 to 10 carbon atoms.

7. The sulfur-containing siloxane according to claim 1, which is bis(2,4,6,8-tetramethylcyclotetrasiloxanyl)sulfide represented by the following formula (4):

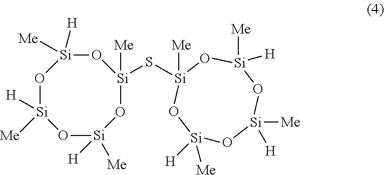 [SMILES: C[SiH]1O[SiH](C)O[Si](C)(S[Si]2(C)O[SiH](C)O[SiH](C)O[SiH](C)O2)O[SiH](C)O1]

8. The sulfur-containing siloxane according to claim 1, which is represented by the following formula (5): 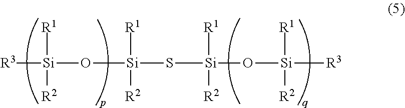
wherein, in the formula (5),
R¹ to R³, at each occurrence, are each independently a hydrogen atom, or a monovalent aliphatic hydrocarbon group having 1 to 10 carbon atoms; and
p and q are each independently an integer of 1 to 5.

9. The sulfur-containing siloxane according to claim 1, which is represented by the following formula (6): 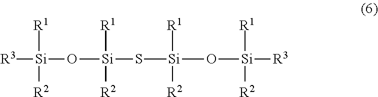
wherein, in the formula (6),
R¹ to R³, at each occurrence, are each independently a hydrogen atom, or a monovalent aliphatic hydrocarbon group having 1 to 10 carbon atoms.

10. The sulfur-containing siloxane according to claim 1, which is bis(1,1,1,3,3-pentamethyldisiloxan-3-yl)sulfide represented by the following formula (7):

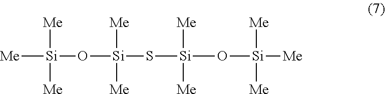 [SMILES: C[Si](C)(C)O[Si](C)(C)S[Si](C)(C)O[Si](C)(C)C]

11. A precursor for a silicon-containing film, comprising the sulfur-containing siloxane according to claim 1.

12. The precursor according to claim 11, wherein the silicon-containing film is formed by chemical vapor deposition.

13. The precursor according to claim 11, wherein the silicon-containing film is formed by an atomic layer deposition method.

14. A composition for forming a silicon-containing film, which comprises the sulfur-containing siloxane according to claim 1.

15. The composition according to claim 14, wherein the silicon-containing film is formed by chemical vapor deposition.

16. The composition according to claim 14, wherein the silicon-containing film is formed by an atomic layer deposition method.

17. A method for producing a sulfur-containing siloxane represented by the following formula (1): 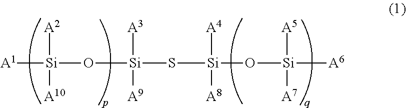
wherein, in the formula (1),
A¹ to A¹⁰, at each occurrence, are each independently a hydrogen atom, an organic group, a halogen, a siloxy group represented by OSiR^{a}R^{b}R^{c}, or an amino group represented by NR^{d}R^{e}; provided that A¹ and A³ optionally become one to be an oxygen atom to thereby form a cyclic siloxane, and provided that A⁴ and A⁶ optionally become one to be an oxygen atom to thereby form a cyclic siloxane;
R^{a} to R^{e}, at each occurrence, are each independently a hydrogen atom, or an organic group, and R^{d} and R^{e} are optionally combined with each other to form a ring; and
p and q are each independently an integer of 1 to 5;
wherein the method comprises:
(a) the step of synthesizing the sulfur-containing siloxane from a raw material siloxane; and
(b) the distillation step of isolating the sulfur-containing siloxane by distillation.

18. The method for producing a sulfur-containing siloxane according to claim 17, wherein in the step (a), the raw material siloxane is reacted with a sulfurizing agent to synthesize the sulfur-containing siloxane.

19. The method for producing a sulfur-containing siloxane according to claim 17, wherein the raw material siloxane is a compound represented by the following formula (8-3): 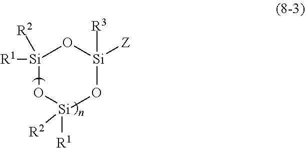
wherein, in the formula (8-3),
R¹ to R³, at each occurrence, are each independently a hydrogen atom, or a monovalent aliphatic hydrocarbon group having 1 to 10 carbon atoms;
Z is a halogen or a hydrogen atom; and
n is an integer of 1 to 4;
or a compound represented by the following formula (8-4): 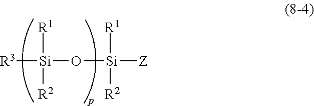
wherein, in the formula (8-4),
R¹ to R³, at each occurrence, are each independently a hydrogen atom, or a monovalent aliphatic hydrocarbon group having 1 to 10 carbon atoms;
Z is a halogen or a hydrogen atom; and
p is an integer of 1 to 5.

20. A method for producing a silicon-containing film, which uses a sulfur-containing siloxane represented by the following formula (1): 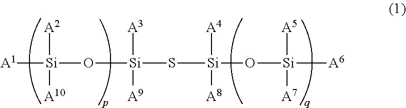
wherein, in the formula (1),
A¹ to A¹⁰, at each occurrence, are each independently a hydrogen atom, an organic group, a halogen, a siloxy group represented by OSiR^{a}R^{b}R^{c}, or an amino group represented by NR^{d}R^{e}; provided that A¹ and A³ optionally become one to be an oxygen atom to thereby form a cyclic siloxane, and provided that A⁴ and A⁶ optionally become one to be an oxygen atom to thereby form a cyclic siloxane;
R^{a} to R^{e}, at each occurrence, are each independently a hydrogen atom, or an organic group, and R^{d} and R^{e} are optionally combined with each other to form a ring; and
p and q are each independently an integer of 1 to 5.
